(19) United States
(12) Patent Application Publication
(10) Pub. No.: US 2005/0227508 A1
(43) Pub. Date: Oct. 13, 2005

(54) Microengineered electrical connectors

(76) Inventor: Richard Syms, London (GB)

Correspondence Address: WALLENSTEIN WAGNER & ROCKEY, LTD, 311 SOUTH WACKER DRIVE, 53RD FLOOR, CHICAGO, IL, 60606, US

(21) Appl. No.: 10/503,536

(22) PCT Filed: Jan. 27, 2003
(86) PCT No.: PCT/GB03/00314

§ 371 Date: Aug. 4, 2004

(30) Foreign Application Priority Data
Feb. 8, 2002 (GB) 02030447.6

(51) Int. Cl. H05K 1/00

(52) U.S. Cl. 439/66; 29/877

(57) ABSTRACT

A miniature, multi-element electrical connector fabricated using micro-electro-mechanical systems technology is described. Shaped elastic cantilever elements (12) are formed on the female part (11) by deposition of conducting material on a surface that has been previously shaped to define a localised contact area and a sloped entrance face. The cantilevers (12) are then undercut. A similar process is used to construct a sloping face on the male part (10) for easy insertion. An etching process is used to fabricate an interlocking alignment system (20, 21, 22) on the two parts. Erosion of a convex corner is used to form a tapered entrance (22) to this alignment system.

### BACKGROUND

The development of small electrical connectors containing a high density of interconnections is becoming increasingly important as electronic systems are miniaturised for portable appliances. Many of the requirements of such connectors are similar to those of optical fibre connectors, since each system requires the simultaneous formation of a multiplicity of closely spaced connections. The fabrication methods of micro-electro-mechanical systems (MEMS) are highly appropriate, because they may form complex, accurately defined three-dimensional structures, that may also contain moving parts.

A number of MEMS fabrication methods exist. The oldest process, bulk micromachining, exploits differences in etch rates between the different crystallographic directions of silicon obtained with particular wet chemical etchants, to form features that follow crystal planes (Petersen 1982; Kovacs et al. 1998).

In a bulk micromachining process, the silicon substrate is first masked with an etch-resistant surface layer (which may be of SiO₂ for the etchant ethylene diamene pyrocatechol (EDP), or of Si₃N₄ for the etchant potassium hydroxide (KOH)), and the substrate is then immersed in the etchant. Generally, the (111) crystal planes etch the slowest, so that in (100) oriented substrates the resulting features contain sloping faces as shown in FIG. 1. The angle θ between the planes in this case is:
θ=cos⁻¹(1/√3)=57.74°. (1)

Depending on the geometry of the mask pattern, the etched features may be V-shaped grooves as shown in FIG. 2a or pits with sloping side walls as shown in FIG. 2b. However, simple surface shapes bounded by (111) crystal planes are only obtained for certain mask patterns, particularly those of closed rectilinear form.

If the mask pattern contains exposed convex corners, these are typically undercut by the exposure of other crystal planes as shown in FIG. 2c (Lee 1969; Bean 1978). Some compensation against undercutting may be provided by incorporating additional features in the mask pattern. These protect the exposed corner against the etchant, but normally only for a specific etching time (Wu 1989; Peurs 1990). The erosion of convex corner features is a convenient method of forming a tapered entrance to a V-groove.

More complex structures may be constructed using more than one anisotropically etched silicon wafer. For example, FIG. 3 shows the construction of an alignment system by anisotropic etching of (100) Si. Here, one substrate has been etched to form a V-shaped alignment groove, while the other has been etched to form a similar ridge. When the two wafers are placed together, the two cross-sections interlock to fix their lateral positions accurately. The two wafers may still slide along the groove direction.

The relative heights of the original wafer surfaces may be found in terms of the mask widths w₁₀ and w₂₀ used to form the two features as follows. At a distance y from the surface of each wafer, the widths w₁ and w₂ of the two features are:
w₁=w₁₀−2y cot(θ)
w₂=w₂₀+2ycot(θ) (2)

When the surfaces are placed together, the relative separation y of the wafer surfaces may be found by solving the equations w₁=w₂₀ or w₂=w₁₀. In either case, y is found as:
y=(½) {w₁₀−w₂₀}tan(θ)=(1/√2){w₁₀−w₂₀} (3)

Thus, the relative height is determined only from the initial mask dimensions w₁₀ and w₂₀.

It was quickly recognised that the V-shaped grooves obtained by anisotropic etching of Si can provide a kinematic mount for cylindrical objects such as optical fibres (Schroeder 1977). The use of lithographic definition allows accurate definition of fibre separation in a ribbon cable, and the use of crystal etching provides accurate location of the fibre axis. Several fibre connectors have been developed using this principle (Fujii 1979, Chang 1987). FIG. 4 shows a multiple fibre connector that combines the use of V-shaped fibre mounting grooves with the alignment system of FIG. 3 (Holmes 1989).

Bulk micromachining can also be used to make movable suspended structures, by under-cutting etch-resistant features. The features can be made from silicon itself, because its etch rate can be controlled by doping. Alternatively, other etch resistant materials may be used. Elastic cantilevers have found application in electrical packaging. For example, they have been used simultaneously to locate and to connect to electrical components inserted into small pits etched into substrates (Strandman 1998; EP933012A1).

Although the features formed by bulk micromachining may be very deep, the range of possible shapes is very restricted. An alternative etch process uses an inductively coupled plasma (ICP) etcher and specialised etch chemistry to form very deep features with almost vertical sidewalls, based on arbitrary mask shapes (Laermer 1996; Kong 1997; Hynes 1999). This form of deep reactive ion etching DRIE) has also been used to form electrical connectors based on suspended elastic cantilevers (Tixier 2000; Mita 2000).

Another MEMS, surface micromachining, exploits the differences between polysilicon and silica to form three-dimensional features (U.S. Pat. No. 4,740,410; Fan 1988; Guckel 1989; Bustillo 1998). The process is based on complementary metal oxide semiconductor (CMOS) technology, together with deposition of polysilicon mechanical layers on top of silica sacrificial layers, which are later etched away. The cycle of deposition, patterning and etching of each material can be repeated several times to build up multi-layer structures, and feature shapes can be arbitrary. However, the thickness of the deposited layers is limited to a few microns, and the mechanical and electrical properties of the polysiliconare generally worse than single crystal Si.

Surface micromachining has been used to construct multi-point electrical probes (Lee 1996; Zhang 1999) and electrical microswitches (Sun 1993; Randall 1996; Zavracky 1997; Hiltmann 1999). The reliability and contact physics of MEMS materials such as gold and polysilicon have also been studied (Hyman. 1998; Nikles 2001).

An alternative surface micromachining process uses lithographic exposure of thick photoresist, followed by electroplating, to build up the mechanical parts. In the German LIGA (Lithographie, Galvanoformung, Abformung) process, synchrotron radiation is used as the exposure source. Due to the extremely short wavelength employed (1-20 Å), very deep (500 μm) resist layers can be penetrated without significant diffraction, so that very high aspect ratio structures can be made (Ehrfeld 1990; Menz 1991; Guckel 1998). Cheaper alternatives use excimer lasers or UV mask aligners to achieve a similar aim; these can achieve feature heights of around 200 μm and 20 μm, respectively (Lawes 1996; Lorenz 1997). The parts are usually electroplated in nickel, but replicas may be made in other materials by moulding.

The LIGA process has been used to construct optical fibre and waveguide connectors (Rogner 1991; Gerner 1995), and also electrical connectors (Ehrfeld 1990; EP0184608). The cheaper UV-LIGA method has also been used to construct similar electrical microconnectors (Bhuiyan 2000; Unno 2001).

FIG. 5 shows an electrical connector formed by LIGA (after EP0184608). Here, lithographic definition is used to construct a mould for the connector elements and the alignment system in a single deep exposure. Because arbitrary patterns may be used, the connector elements may be shaped to allow easy insertion and removal. The mould is then filled with metal by electroplating. After removal of the mould, the parts are freed from the substrate by removal of material from beneath, to allow motion.

Although this arrangement involves a simple fabrication process, it suffers from some disadvantages. For example, the use of in-plane patterning implies that each female connector element must deflect parallel to the substrate when the corresponding male connector element is inserted. The requirement for lateral clearance limits the interconnect density achievable, because the elastic parts must be of sufficient thickness and be deflected by a sufficient distance to obtain a suitably high contact force, and hence to obtain a sufficiently low contact resistance.

Furthermore, because the connector elements are formed from a single layer of material, their elastic and electrical properties cannot easily be separated. It is therefore difficult to optimise the electrical properties for high-speed operation. There is therefore a requirement for alternative methods of constructing fine-pitch electrical connectors.

### SUMMARY OF THE INVENTION

It is an object of the present invention to provide a microengineered electrical connector that can achieve much higher interconnect densities. Thus, according to the present invention, a method of manufacturing an electrical connector element comprises depositing a conductive, flexible material onto a profiled portion of the surface of a substrate to form an electrode and removing substrate material from beneath a portion of the electrode, thus allowing the electrode to be flexed into or out of the surface of the substrate whilst being supported by a remaining portion of the substrate material. Since the flexible electrode can be deflected normal to the substrate, a high contact force can be obtained without limiting the packing density.

Preferably, the deposited conductive, flexible material forms an elongate electrode, thus allowing a number of such electrodes to be densely laterally arrayed. In such a case, a cantilevered electrode may be advantageous, in which case substrate material is removed from beneath one end of the electrode, thus allowing that end of the electrode to be flexed into or out of the surface of the substrate whilst the other end is supported by a remaining portion of the substrate material.

A preferred shape of electrode will include a raised portion that is adapted to make electrical contact with an electrode of a second connector element. For this reason, the said portion of the surface of the substrate preferably includes a protrusion and the substrate material removed includes that protrusion. A protrusion in the form of a rib allows one or more elongate electrodes to be formed by depositing suitable elongate regions of conductive, flexible material extending across the rib.

For convenience of manufacture, the said portion of the surface of the substrate may include a depression with the protrusion located within the depression. Again, where the substrate is a silicon substrate, the depression and the protrusion may concurrently be formed with a single anisotropic etch. Preferably, the deposited conductive, flexible material forms an elongate electrode extending into the depression and the substrate material removed includes a portion of the depression, but does not include that part of the substrate from which the elongate electrode extends into the depression.

As discussed above, the method is particularly applicable to the manufacture of a connector element with a number of electrode. Thus, the deposited conductive, flexible material preferably forms a plurality of such electrodes and the substrate material is preferably removed from beneath a corresponding portion of each electrode, thus allowing each electrode to be flexed into or out of the surface of the substrate whilst being supported by a remaining portion of the substrate material.

The plurality of electrodes are linked by a bar of insulating material, causing them to flex together. An actuator may be formed by means of which the plurality of electrodes are flexed.

To assist in the location of a cooperating second electrical connector element, the surface of the substrate may include a locating profile. Where the substrate is a silicon substrate, the depression, the protrusion and the locating profile may concurrently be formed with a single anisotropic etch.

Preferably, the locating profile comprises one or more elongate ribs or grooves. This makes for simple sliding assembly of the two connector elements.

The electrodes may be constructed as multi-layers, so there is additional scope to deposit a layer of elastic or other material beneath them to alter their mechanical properties. Thus, the flexible, conductive material may be deposited onto a layer of insulating material on the surface of the first substrate.

Because two connector elements are needed to make a connection, the method may further comprise manufacturing a second, cooperating electrical connector element by depositing a conductive material onto the surface of a second substrate to form an electrode. Since the electrode on the second substrate need not flex, the portion of the surface of the second substrate onto which it is deposited may be substantially flat. Nonetheless, other parts of the surface of the second substrate may be profiled. Where the second substrate is a silicon substrate, its surface is preferably profiled by anisotropic etching.

The surface of the second substrate may include a depression to facilitate its assembly with the first connector element. It may also include a locating profile for locating the first electrical connector element. Where the second substrate is a silicon substrate, the depression and the locating profile may concurrently be formed with a single anisotropic etch.

The locating profile on the surface of the second substrate may comprises one or more elongate ribs or grooves. Preferably, the locating profile on the surface of the first substrate includes one or more ribs and the locating profile on the surface of the second substrate includes one or more grooves, each groove including a tapered mouth to facilitate location of its corresponding rib. Where the second substrate is a silicon substrate, each groove and its tapered mouth may concurrently be formed with a single anisotropic etch. Preferably, for an efficient manufacturing process, the two elements are manufactured together with the depression, the protrusion and the one or more ribs on the first substrate and the depression and the one or more grooves and their tapered mouths on the second substrate being formed with a single anisotropic etch.

Again, the conductive material may be deposited onto a layer of insulating material on the surface of the second substrate.

Where anisotropic etching is used, the profiled surface of the substrate or substrates may subsequently be smoothed.

The present invention also provides an electrical connector element in the manufacture of which the method of the invention is performed. An electrical microconnector consisting of two substrates, the first of which carries an array of flexible electrodes, and the second of which carries a corresponding array of electrodes is also provided.

### BRIEF DESCRIPTION OF THE DRAWINGS

The present invention will now be described by way of example with reference to the accompanying drawings, in which:

FIG. 1 shows the formation of trench bounded by (111) planes by anisotropic etching of silicon;

FIG. 2 illustrates etched features obtained by anisotropic etching of (100) silicon;

FIG. 3 shows the construction of an alignment system by anisotropic etching of (100) silicon;

FIG. 4 shows a ribbon optical fibre connector based on anisotropically etched silicon;

FIG. 5 shows an electrical connector fabricated by the LIGA process;

FIG. 6 is a schematic of a female connector element according to the present invention;

FIG. 7 is a schematic of a corresponding male connector element;

FIG. 8 schematically shows the process of assembling the connector;

FIG. 9 are cross-sections of the connector elements, showing the deflection of the flexible electrodes;

FIG. 10 illustrates an example fabrication process for the simultaneous formation of the male and female connector elements; and

FIG. 11 shows the female connector element, incorporating an additional link bar on the flexible electrodes.

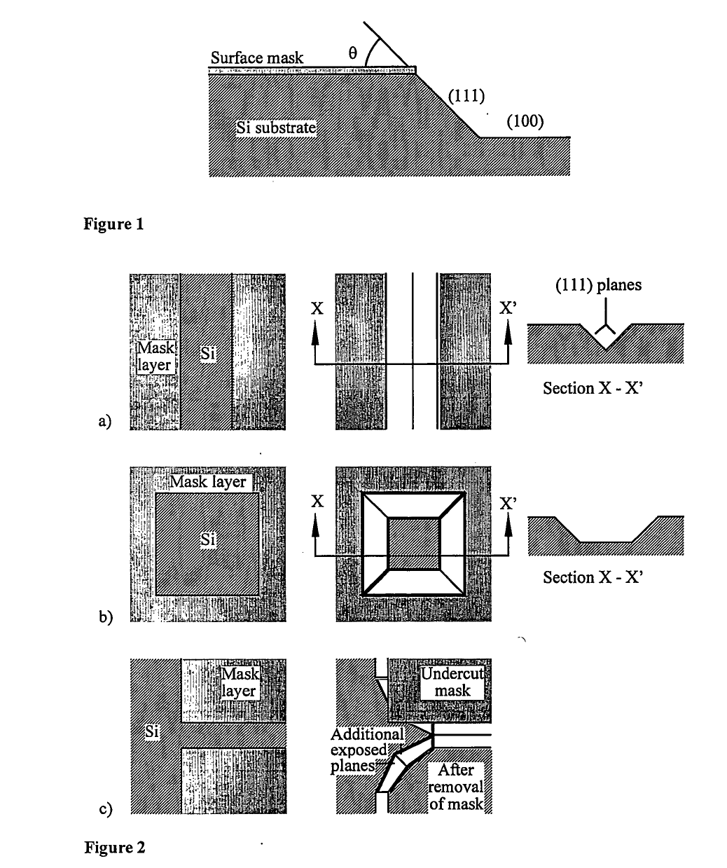

### DETAILED DESCRIPTION OF THE INVENTION

There follows a description of a miniature, multi-pin electrical connector fabricated using silicon-based micro-electro-mechanical systems (MEMS) technology. The design overcomes many limitations of conventional or known connectors. Particularly, the elastic cantilever elements are now deflected normal to the substrate, so that a high contact force may still be obtained without limiting the achievable packing density.

To obtain a suitably shaped flexible cantilever element without the use of in-plane patterning, the substrate of the female part is first patterned and etched to form a non-planar surface. The cantilever elements are then formed by deposition of conducting material on this surface. The surface shape is chosen to form a localised contact area, and a sloped entrance face. The cantilevers are then undercut. A similar etching process is also used to construct a sloped entrance face on the male part for easy insertion.

An anisotropic etching process is used to fabricate an alignment system consisting of interlocking grooves, so that the conductors are correctly orientated and positioned when the two parts of the connector are assembled. Erosion of a convex corner by an etching process is used to form a tapered entrance to this alignment system.

Because the cantilevers may be constructed as multi-layers, there is additional scope to deposit a layer of elastic material beneath the conductors to alter their mechanical properties. The conductors may also be constructed as transmission line elements for high-speed operation. Finally, because all the cantilevers are now deflected in the same direction, there is scope to incorporate an additional mechanism to open the connector.

Because of its small size, applications for the invention include flying lead connections in portable electronic appliances such as hand-held audio equipment, games playing equipment and mobile phones. However, because the fabrication process involves micro-machining of silicon, the invention may also be used for direct interconnection of plug-in silicon circuitry such as memory cards and smart cards.

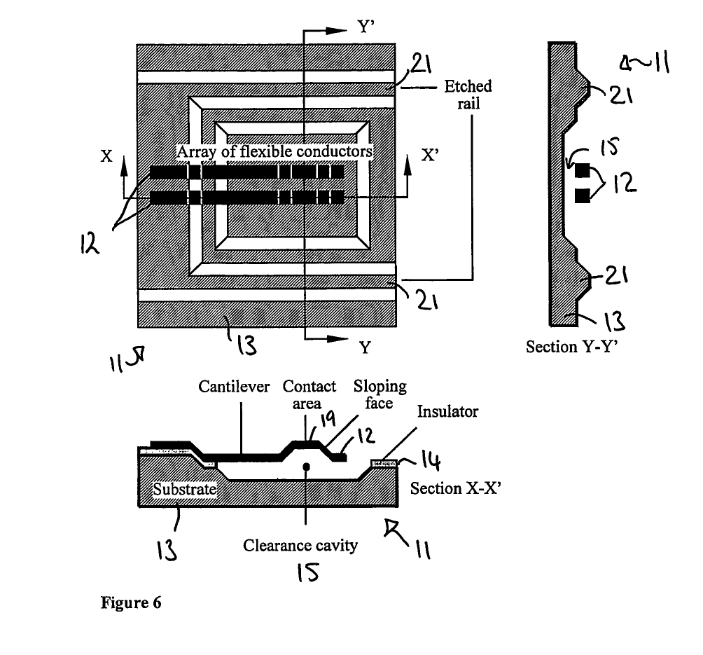

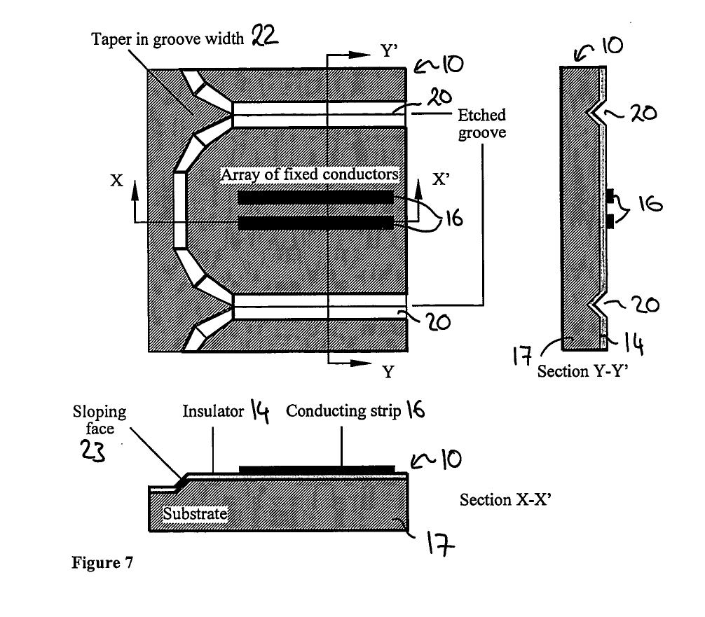

As shown in FIGS. 6 and 7, the connector comprises two parts: a male part 10 (FIG. 7) and a female part 11 (FIG. 6). The female part 11 contains a set of parallel, flexible conducting strips 12; which are arranged as a set of suspended cantilever beams mounted on a substrate 13. The substrate 13 may be an insulator, or a conductor or semiconductor covered by an insulating layer 14. In a MEMS fabrication process, the substrate 13 may conveniently be silicon, covered in a layer 14 of SiO₂, Si₃N₄ or another compatible insulating material.

In an electrical connector, low contact resistance is obtained by forming the contacting surface from materials with high conductivity, low tendency to oxidisation and low tendency to other forms of corrosion. These include (but are not restricted to) noble metals such as gold, and gold alloyed with other materials to increase its hardness or wear resistance. In a MEMS fabrication process, these materials may be deposited on surfaces by vacuum deposition, electroplating or a combination of the two. Suitable features may be formed by lithography and etching, by deposition through a shadow mask or by electroplating inside a lithographically defined mould.

A clearance cavity 15 is provided beneath the cantilevers 12 so that they may be deflected towards the substrate 13. This cavity 15 is formed by removing the substrate material from directly beneath the cantilevers 12, leaving them fixed to the substrate 13 at one end. The material may be removed by etching the front side of the substrate, or from the rear.

In MEMS processing, there is a variety of suitable substrate etching methods. These include (but are not restricted to) wet chemical etching and deep reactive ion etching.

Depending on which fabrication approach is adopted, a number of different etching methods may be appropriate. For example, if front-side etching is used, an etching process with some degree of isotropy may be preferred, so that the cantilevers 12 may easily be undercut. Alternatively, if a backside etching process is used, a DRIE process may be preferred, so that the etched feature is well defined.

The male part 10 contains a set of parallel, fixed conducting strips 16 on a rigid substrate 17. The strips 16 are arranged to lie on the same pitch as the strips 12 on the female part 11. An electrical connection is made by contacting each strip 16 from the male part 10 of the connector with its counterpart 12 from the female part 11.

Each rigid connecting strip 16 in the male part 10 is used to depress the appropriate flexible strip 12 from the female part 11, so that a suitable contact force between the two is provided by the elasticity of the cantilever 12. The elastic force is determined by the cantilever dimensions, composition and deflection. There is scope to engineer the properties of the cantilever 12 by forming it as a bi-layer, consisting of an upper conducting layer on a lower elastic layer.

The parameters of the conducting layer may be adjusted to optimise the electrical properties of the connector. The lower elastic layer may be a metal or an insulator. In a MEMS fabrication process, examples of the former include (but are not restricted to) Ni, which may again be conveniently deposited by electroplating. Examples of the latter include (but are not restricted to) Si₃N₄. The parameters of the elastic layer may be adjusted to optimise the mechanical properties of the connector.

The cantilevers 12 are shaped along their length by depositing the conducting layer on a surface that has previously been shaped into a well-defined topography. The surface topography may again be formed using MEMS etching processes, and provides a number of features. Firstly, the outermost section 18 of the cantilever 12 is sloped down towards the substrate 13, to provide a smooth face that may easily be deflected towards the substrate 13 when the two halves of the connector are assembled. Secondly, a section of the cantilever 12 adjacent to the outermost sloping face 18 is raised to define a well-defined contact surface 19.

There are two simple methods for the fabrication of appropriately shaped flexible connector elements. Firstly, etching may be used to create a non-planar substrate. For example, using (100)-oriented silicon, a suitable surface may be created by anisotropic etching down crystal planes. Secondly, deposition of an additional material in patterned strips may be used to create the non-planar surface. The non-planar surface is then coated with an insulating layer 14 and with conductors 12, which are patterned into strips.

In either case, the non-planar surface may be further modified after its initial formation, to remove sharp corners. For example, an etched silicon surface may be smoothed by thermal oxidation, followed by etching of the resulting oxide. Alternatively, a deposited strip 12 may be smoothed by a melting step.

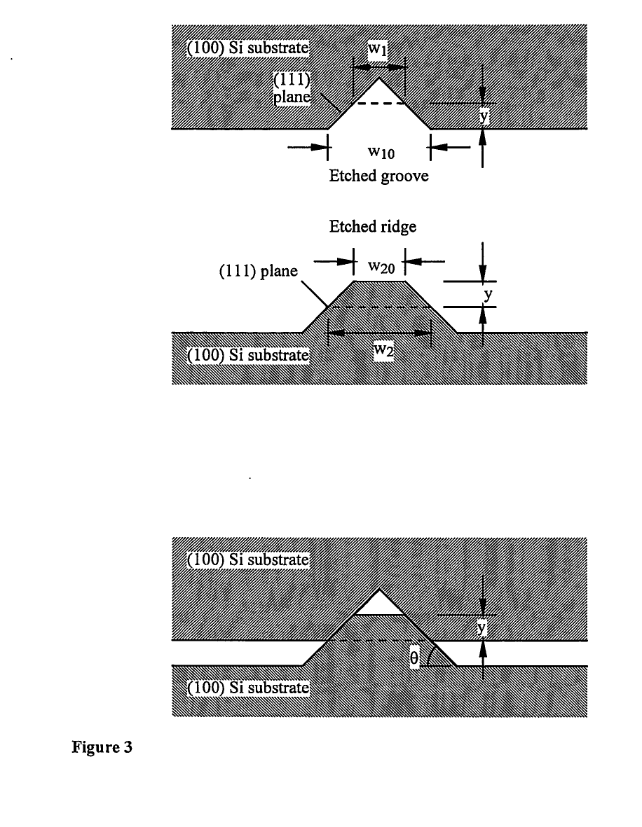

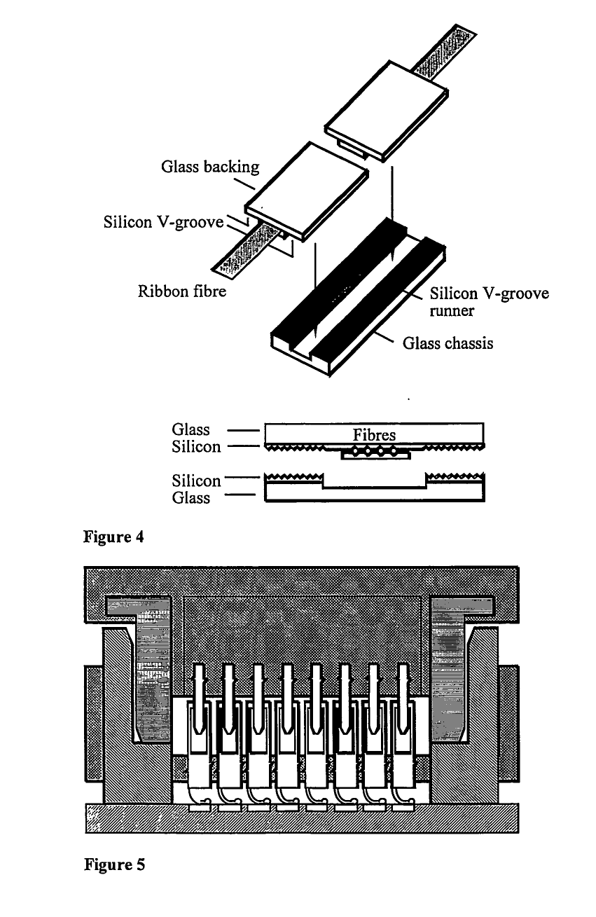

Because the pitch and separation of the conducting strips 12, 16 is ideally small, a mechanical alignment arrangement is needed to ensure that the male and female strips 12, 16 contact correctly, without introducing a short circuit between adjacent strips. The mechanical alignment system should also ensure that the elastic cantilevers 12 are deflected through a known distance, so that a known and repeatable contact force is obtained. A suitable arrangement can be obtained by etching the two substrates 13, 17 using MEMS techniques to form an interlocking guidance feature as previously shown in FIG. 3.

FIGS. 6 and 7 show schematic of the male and female parts of a connector containing interlocking alignment features. Here the male part 10 carries V-shaped alignment grooves and the female part 11 carries alignment ridges 21, but this arrangement is not exclusive. The alignment grooves 20 on the male part 10 have a tapered entrance 22 to assist in assembly. This feature is formed by under-cutting the convex corners of a mask pattern, as previously shown in FIG. 2c. The grooves 20 in the male part 10 may also be terminated, to prevent over-insertion. The rigid conducting strips 16 on the male part 10 have been set back from the tapered entrance 22, so that they may only contact the flexible strips 12 on the female part after proper alignment has been achieved. The male part 10 also has a sloped entrance face 23 to assist in depressing the flexible cantilevers 12 towards the substrate 13. The material beneath the flexible cantilevers 12 has now been removed from the front side rather than from the back, but this arrangement is not exclusive.

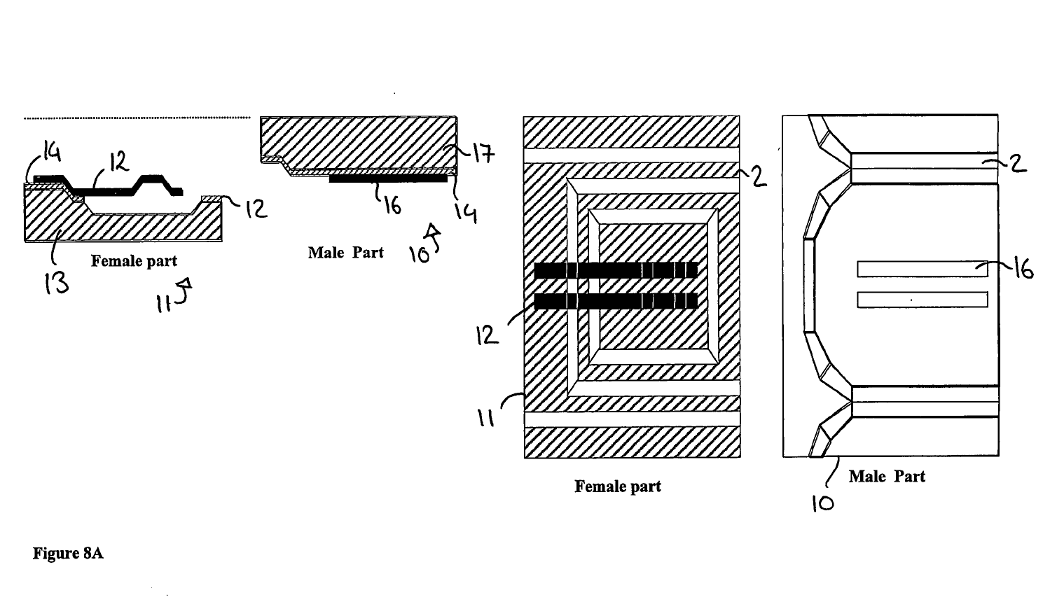

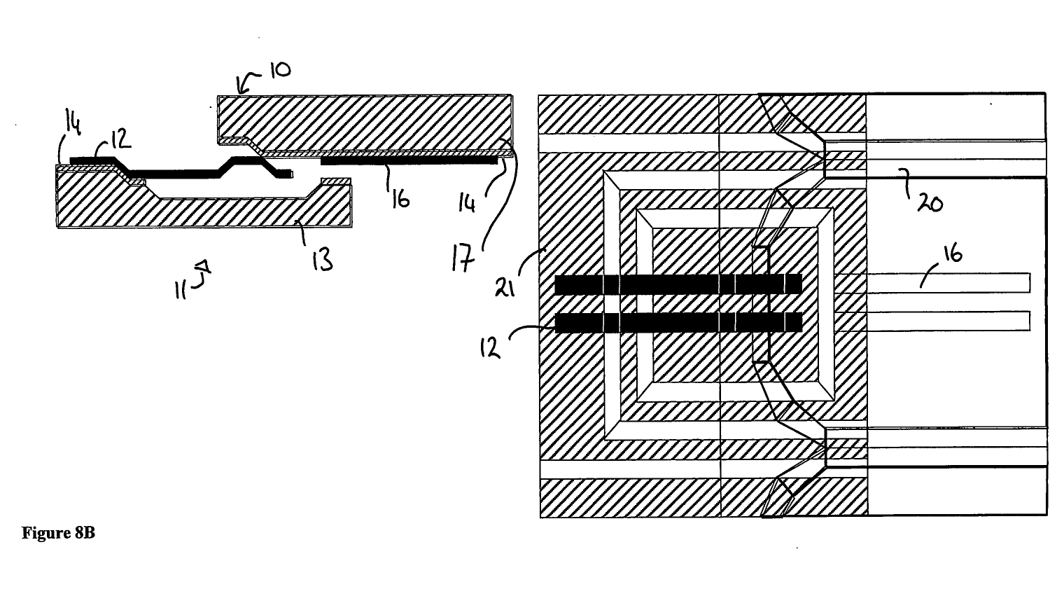

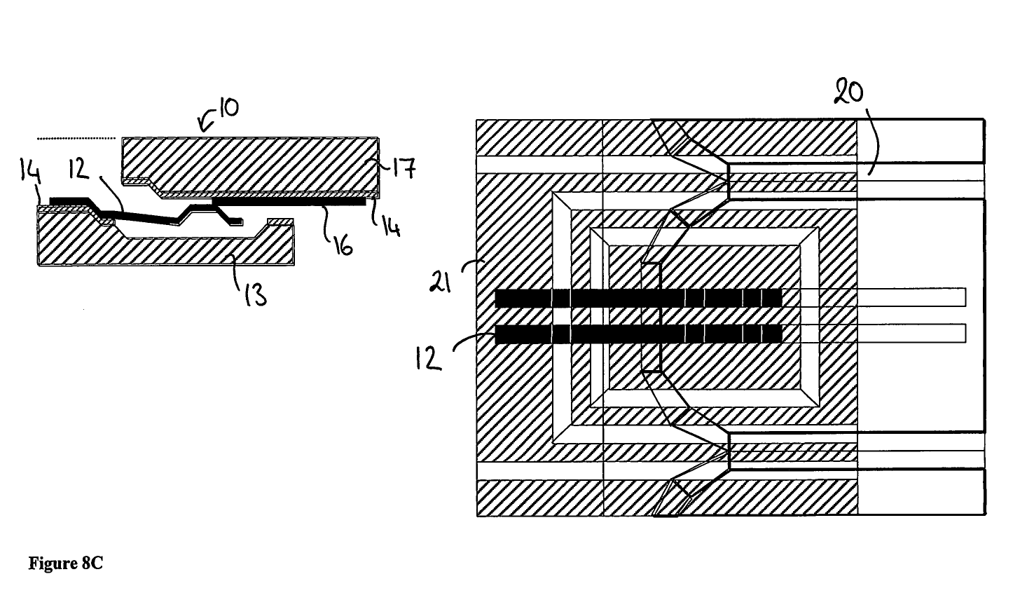

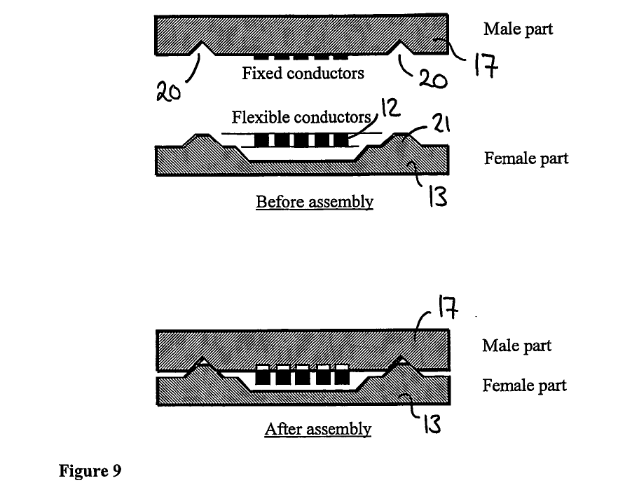

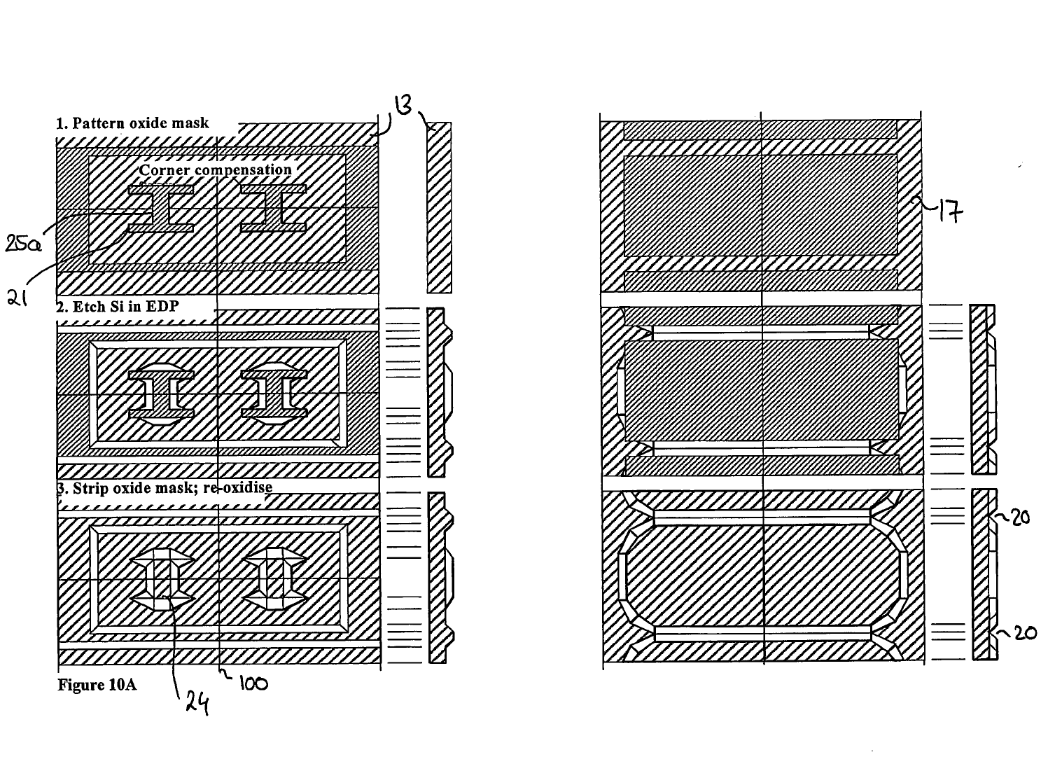

FIG. 8 shows the process of assembling the connector, and FIG. 9 shows how the mechanical alignment system may be used to ensure deflection of the flexible cantilevers 12 through a known distance using the geometry previously shown in FIG. 3. In FIG. 8 the views on the left hand side are side views of the assembly process whereas those on the right hand side are plan views. In FIG. 8a, the male and female components are separate from one another. FIG. 8b shows an initial presentation of the male part to the female, and it is readily observable that the assembly process provides for an initial abutment of a lower surface of the male member or part with the flexible strip 12 provided on an upper surface of the female part. Further alignment or co-operation between the two parts as is shown in FIG. 8c provides for a deflection of the flexible strip 12 downwardly towards the substrate 13. As can be seen from the plan view of FIG. 8c, this assembly process serves to bring the conducting strips 16 on the lower portion of the male member 10 into contact with the co-operating cantilever 12 on the upper surface of the female member or part 11.

As shown in the sectional views of FIG. 9 the co-operation or mating achieved by the bringing of the two parts together is effected by an alignment of the ridge 21 provided on the female connector with a recess 20 formed in the male connectors. On inter-engagement one is received within the other.

Some care is required to allow simultaneous fabrication of the two parts 10, 11 of the connector, and also to allow the incorporation of mechanical alignment features 20, 21.

Particularly, if the ridge 24 over which the flexible conducting strips are deposited is formed from silicon, it must now contain convex corners, which must be protected against erosion by incorporation of additional features 25 in the mask pattern.

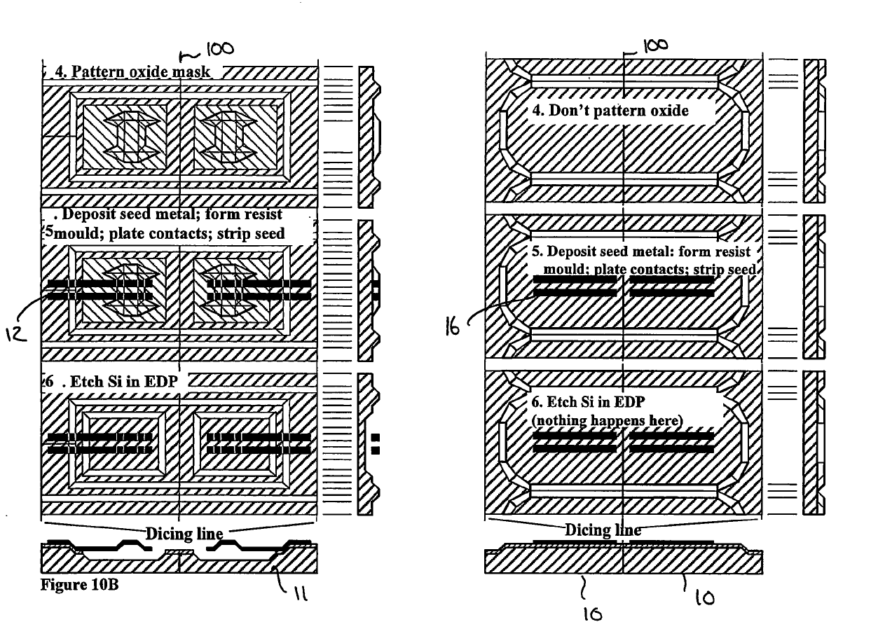

FIG. 10 shows an example fabrication process for a complete connector, involving three lithographic steps. Both the male 10 and female 11 parts are fabricated together, in different areas of the same wafer. The male and female parts 10, 11 are fabricated as back-to-back pairs, which are separated by sawing the wafer, typically at the end of the fabrication process.

In step 1, a (100) oriented silicon wafer is oxidised, and the oxide layer is then patterned using Mask #1. The pattern forming the ridge 24 over which the conductors are deposited has the shape of a capital letter I. The two horizontal strokes 25 of the letter are corner compensation features, which serve to protect the vertical stroke 25a of the letter from erosion during the first etching step. In step 2, anisotropic etching is used to create a terraced substrate surface. Typically this is effected by etching the Si in EDP. Additional crystal planes are exposed beneath the corner compensation features. The exact form of these planes is not important, since they will be removed during a subsequent etching step.

In step 3, the oxide layer is removed, and the wafer is then re-oxidised to form a thick insulating layer. In step 4, the oxide layer of the wafer that will be used for the female connector is patterned using a second mask, Mask #2. The wafer used in the formation of the male connector is not patterned. In step 5, an electroplating seed layer (typically a seed metal layer) is deposited, followed by thick layer of photoresist. The thick resist is exposed and developed to form a deep mould, using Mask #3. Conducting strips 12, 16 are then deposited inside the mould by electroplating. The resist and any unwanted portions of the seed layer are then removed. In step 6, the substrate 13 is removed from beneath the conductors 12 by further anisotropic etching, again typically using EDP. Finally, the wafer is sawn along the dicing lines 100 to form separated male and female parts 10, 11.

The exact order of the individual steps shown is representative, and other processes that achieve a similar final result are clearly possible.

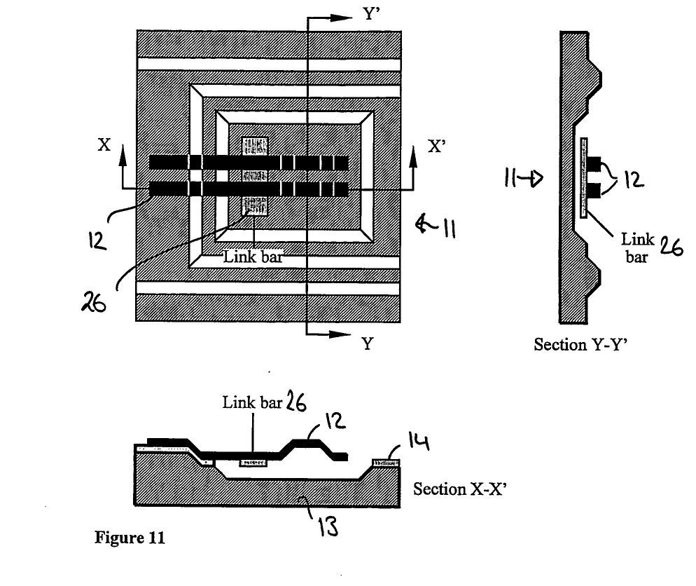

Further refinements are possible, for example to convert the connector into a micro-engineered equivalent of a “zero-insertion-force” (or ZIF) socket. FIG. 11 shows a female part 11 that incorporates an additional bar 26 of material linking the conducting strips 12. The bar 26 should be formed from an insulating material so that the strips 12 are not short-circuited, but it may have conducting regions at its extremities. The bar 26 is located at a suitable distance from the free end of the cantilevers 12, so these may still deflect independently. However, the bar 26 is also located at a suitable distance from the built-in end of the cantilevers so that depression of the bar towards the substrate will deflect all the cantilevers 12 together. This mechanism may be used to hold the conducting strips 12 on the female part away from the conducting strips 16 on the male part while the connector is being assembled, thus minimising wear of the contact areas.

The force required to depress the bar may be provided by an external actuator. Alternatively, a MEMS actuator may be used. Suitable actuators may be based on electrostatic, electromagnetic, electrothermal and piezoelectric mechanisms (Fujita 1998).

It will be understood that modifications may be made to the device and methodology herein described without departing from the spirit and scope of the invention and it is not intended to limit the invention in any way except as may be deemed necessary in the light of the appended claims. Furthermore the words “downwardly”, “upwardly” and the like are used for ease of explanation and it is not intended to limit the application of the invention to any one specific orientation. Additionally, the words “comprises/comprising” and the words “having/including” when used herein with reference to the present invention are used to specify the presence of stated features, integers, steps or components but does not preclude the presence or addition of one or more other features, integers, steps, components or groups thereof.

### REFERENCES

Bulk Micromachining

Petersen K E. “Silicon as a mechanical material” Proc. IEEE 70, 420-457 (1982)
Kovacs G. T. A., Maluf N. I., Petersen K. E. “Bulk micromachining of silicon” Proc. IEEE 86, 1536-1551 (1998)
Lee D. B. “Anisotropic etching of silicon” J. Appl. Phys. 40, 4569-4574 (1969)
Bean K. E. “Anisotropic etching of silicon” IEEE Trans. Electron Devices ED-25, 1185-1193 (1978)
   Corner Compensation in Anisotropic Etching
Wu X.-P., Ko W. H. “Compensating corner undercutting in anisotropic etching of (100) silicon” Sensors and Actuators 18, 207-215 (1989)
Peurs B., Sansen W. “Compensation structures for convex corner micromachining in silicon” Sensors and Actuators A21-23, 1036-1041 (1990)
   Silicon Fibre Connectors
Schroeder C. M. “Accurate silicon spacer chips for an optical fiber cable connector” Bell. Syst. Tech. J. 57, 91-97 (1977)
Fujii Y., Minowa J., Suzuki N. “Demountable multiple connector with precise V-grooved silicon” Elect. Lett. 15, 424-425 (1979)
Chang P. C., Sriram S., Wey A. C. “Multiple fiber interconnect using silicon V-grooves” Proc. SPIE 836, 311-318 (1987)
Holmes A. S., Syms R. R. A. “Self-aligning guided wave breadboard system for delay line signal processing” Proc. 7th Int. Conf. on Fibre Optics and Optoelectronics, April 25-27, London, Pp 3.4-3.9 (1989)
   Electrical Microconnectors by Anisotropic Etching of Si
Strandman C., Bäcklund Y. “Passive and fixed alignment of devices using flexible silicon elements formed by selective etching” J. Micromech. Microeng. 8, 3944(1998)
Bäcklund Y., Strandman C. “Method and device for positioning and retaining micro-building blocks” European Patent EP 933012A1 Aug. 4 (1999)
   DRIE
Laermer F., Schilp A. “Method of anisotropically etching silicon” U.S. Pat. No. 5,501,893 March 26th (1996)
Kong S., Minami K., Esashi M. “Fabrication of reactive ion etching systems for deep silicon machining” Trans. Inst. Electr. Engng. Jpn. 117-E, 10-14 (1997)
Hynes A. M., Ashraf H., Bhardwaj J. K., Hopkins J., Johnston I., Shepherd J. N. “Recent advances in silicon etching for MEMS using the ASE™ process” Sensors and Actuators 74, 13-17 (1999)
   Electrical Microconnectors by DRIE of Si
Tixier A., Mita Y., Oshima S., Gouy J.-P., Fujita H. “3D microsystem packaging for interconnecting electrical, optical and mechanical devices to the external world” Proc. 13^{th} Ann. Workshop on Micro-electromechanical systems (MEMS 2000) 23-27 January, Miyazaki, Japan, Pp 698-705 (2000)
Mita Y., Tixier A., Oshima S., Mita M., Gouy J.-P., Fujita H. “A silicon shadow mask with unlimited patterns and a mechanical alignment structure by A1-delay masking process” Trans. JIBE 120-E, 357-362 (2000)
   Surface Micromachining
Muller R. S. “Micromechanical elements and methods for their fabrication” U.S. Pat. No. 4,740,410 April. (1988)
Fan L. S., Tai Y.-C., Muller R. S. “Integrated movable micromechanical structures for sensors and actuators” IEEE Trans. Electron Devices 35, 724-730 (1988)
Guckel H., Burns D. W. “Fabrication of micromachined devices from polysilicon films with smooth surfaces” Sensors and Actuators 20, 117-122 (1989)
Bustillo J. M., Howe R. T., Muller R. S. “Surface micromachining for microelectromechanical systems” Proc. IEEE 86, 1552-1573 (1998)
   Surface Micromachined Probes
Lee C., Kin Y., Choi Y-G., Cho Y—H., Lee K., Kwak B. M. “High-density silicon microprobe arrays for LCD pixel inspection” 9^{th} Ann. Int. Workshop on Micro Electro Mechanical Systems, 11-15 February San Diego, Calif., Pp. 429-434 (1996)
Zhang Y., Zhang Y., Marcus R. B. “Thermally actuated microprobes for a new wafer probe card” J. Microelectromech. Syst. 8, 4349 (1999)
   Surface Micromachined Switches
Sun X. Q., Ii Z. J., Zheng X. Y., Uu L. T. “Study of fabrication process of electrostatic microswitch and its application to a micromechanical v-f converter” Sensors and Actuators A35, 189-192 (1993)
Randall J. N., Goldsmith C., Denniston D., Lin T.-H. “Fabrication of micromechanical switches for routing radio frequency signals” J. Vac. Sci. Technol. B14, 3692-3696 (1996)
Zavracky P. M., Majumder S., McGruer N. E. ‘Micromechanical switches fabricated using nickel surface micromachining’ J. Micro Electro Mechanical Systems 6, 3-9 (1997)
Hiltmann K., Keller W., Lang W. “Micromachined switches for low electrical loads” Sensors and Actuators 74, 203-206 (1999)
   Surface Micromachined Contacts
Hyman D., Mehregany M. “Contact physics of gold microcontacts for MEMS Switches”44^{th} IEEE Holm Conference on Electrical Contacts, 26-28 Oct. Arlington, Va., USA, pp. 133-140 (1998)
Nikles S., Bledsoe S. C., Bradley R. M., Najafi K. “Reliability and contact resistance of polysilicon beam leads for use in a high density connector” Proc. 14^{th} IEEE Int. Conf. On Micro Electro Mechanical Systems, 21-25 January, Interlaken, Switzerland, Pp 64-67 (2001)
   The LIGA Process
Ehrfeld W. “The LIGA process for microsystems” Proc. Micro System Technologies '90, Berlin, Pp 521-528 (1990)
Menz W., Bacher W., Harmening M., Michel A. “The LIGA technique—a novel concept for microstructures and the combination with Si-technologies by injection molding” Tech. Digest, IEEE Micro Electro Mechanical Systems Workshop, Nara, Japan, January 30- February 2 Pp 69-73 (1991)
Guckel H. “High-aspect-ratio micromachining via deep X-ray lithography” Proc. EEE 86, 1586-1593 (1998)
   UV LIGA
Lawes R. A., Holmes A. S., Goodall F. N. “The formation of moulds for 3D microstructures using excimer laser ablation” Microsystem Technologies 3, 17-19 (1996)
Lorenz H., Despont M., Fahrni N., IaBianca N., Renaud P., Vettinger P. “SU-8: a low-cost negative resist for MEMS” J. Micromech. Microeng. 7, 121-124 (1997)
   LIGA Fibre Connectors
Rogner A., Ehrfeld W., Munchmeyer D., Bley P., Burbaum C., Mohr J. “UGA-based flexible microstructures for fiber-chip coupling” J. Micromech. Microeng. 1, 167-170 (1991)
Gemer M., Paatzsch T., Weber L., Schift H., Smaglinsid I., Bauer H-D., Abraham M., Ehrfeld W. “Micro-optical components for fibre and integrated optics realised by the LIGA technique” IEEE J. Microelectromech. Syst. 4,328 (1995)
   LIGA Electrical Microconnectors
Ehrfeld W., Hagmann P., Munchmeyer D., Becker E. W. “Process for the manufacture of mechanically separable multiconnectors for the electrical connection of microelectronic components, and multiconnectors fabricated by this process” EP0184608 18^{th} June (1986)
   UV-LIGA Electrical Microconnectors
Bhuiyan M. M. I., Unno T., Yokoyama Y., Toriyama T., Sugiyama S. “Micro connector fabricated by micro process technology” Proc. 2000 IEEE Int. Symp. on Micromechatronics and Human Science, Nagoya, JapanPp. 83-88 (2000)
Unno T, Bhuiyan M. M. I, Yokoyama Y., Sugiyama S., Toriyama T. “Micro connector for high packaging density fabricated by using UV thick photoresist” Tech. Dig. of 18^{th} Sensor Symposium, 165-170 (2001)
   Microactuators
Fujita H. “Microactuators and micromachines” Proc. IEEE 86, 1721-1732 (1998)

1. A method of manufacturing an electrical connector element comprising:
depositing a conductive, flexible material onto a profiled portion of the surface of a substrate to form an electrode;
removing substrate material from beneath a portion of the electrode, thus allowing the electrode to be flexed into or out of the surface of the substrate whilst being supported by a remaining portion of the substrate material, and
providing at least one locating profile on the surface of the substrate, the locating profile being adapted to provide, in use, for the location of a second co-operating electrical connector element.

2. A method accordingly to claim 1 in which the deposited conductive, flexible material forms an elongate electrode.

3. A method accordingly to claim 2 comprising the step of removing substrate material from beneath one end of the electrode, thus allowing that end of the electrode to be flexed into or out of the surface of the substrate whilst the other end is supported by a remaining portion of the substrate material.

4. A method according to claim 1 further comprising the step of profiling the surface of the substrate, and depositing the conductive, flexible material onto the profiled surface of the substrate.

5. A method according to claim 4 in which the substrate is a silicon substrate and the surface is profiled by anisotropic etching.

6. A method according to claim 1 in which the said portion of the surface of the substrate includes a protrusion.

7. A method accordingly to claim 6 in which the substrate material removed includes the protrusion.

8. A method according to claim 6 in which the protrusion is a rib.

9. A method according to claim 8 in which the deposited conductive, flexible material forms an elongate electrode extending across the rib.

10. A method according to claim 1 in which the said portion of the surface of the substrate includes a depression.

11. A method according to claim 6 in which the said portion of the surface of the substrate includes a depression and the protrusion is located within the depression.

12. A method according to claim 11 in which the substrate is a silicon substrate, the method comprising concurrently forming the depression and the protrusion with a single anisotropic etch.

13. A method according to claim in which the deposited conductive, flexible material forms an elongate electrode extending into the depression.

14. A method according to claim 13 in which the substrate material removed includes a portion of the depression.

15. A method according to claim 14 in which the substrate material removed does not include that part of the substrate from which the elongate electrode extends into the depression.

16. A method according to claim 1 in which the deposited conductive, flexible material forms a plurality of such electrodes; and the substrate material is removed from beneath a corresponding portion of each electrode, thus allowing each electrode to be flexed into or out of the surface of the substrate whilst being supported by a remaining portion of the substrate material.

17. A method according to claim 16 in which the plurality of electrodes are linked by a bar of insulating material.

18. A method according to claim 17 further comprising forming an actuator by means of which the plurality of electrodes may together be flexed.

19. A method according to claim 11 wherein the steps of forming the depression, the protrusion and the locating profile is effected in a single concurrent anisotropic etch.

20. A method according to claim 17 in which the locating profile comprises one or more elongate ribs or grooves.

21. A method according to claim 1 in which the flexible, conductive material is deposited onto a layer of insulating material on the surface of the first substrate.

22. A method according to claim 1 further comprising the step of manufacturing a second, co-operating electrical connector element by depositing a conductive material onto the surface of a second substrate to form an electrode.

23. A method according to claim 22 in which the portion of the surface of the second substrate onto which the conductive material is deposited is substantially flat.

24. A method according to claim 22 in which the surface of the second substrate is profiled.

25. A method according to claim 24 in which the second substrate is a silicon substrate and its surface is profiled by anisotropic etching.

26. A method according to claim 24 in which the surface of the second substrate includes a depression.

27. A method according to claim 24 in which the surface of the second substrate includes a locating profile for locating the first electrical connector element.

28. A method according to claim 27 in which the second substrate is a silicon substrate and its surface includes a locating profile for locating the first electrical connector element, the method comprising concurrently forming the depression and the locating profile with a single anisotropic etch.

29. A method according to claim 27 in which the locating profile on the surface of the second substrate comprises one or more elongate ribs or grooves.

30. A method according to claim 29 in which the surface of the first substrate includes one or more co-operating ribs or grooves, each groove on one of the substrates being paired with a corresponding rib on the other and each groove including a tapered mouth to facilitate location of its corresponding rib.

31. A method according to claim 30 in which the ribs are on the first substrate and the grooves on the second substrate.

32. A method according to claim 31 in which the second substrate is a silicon substrate, the method comprising concurrently forming each groove and its tapered mouth with a single anistropic etch.

33. A method according to claim 19 in which the surface of the first substrate includes one or more locating ribs, the method further comprising: manufacturing a second, co-operating electrical connector element by depositing a conductive, flexible material onto the surface of a second silicon substrate to form an electrode, the surface of the second substrate including a depression and one or more elongate grooves, each including a tapered mouth to facilitate location of a corresponding rib on the first substrate; and concurrently forming the depression, the protrusion and the one or more ribs on the first substrate and the depression and the one or more grooves and their tapered mouths on the second substrate with a single anisotrepic etch.

34. A method according to claim 22 in which the conductive material is deposited onto a layer of insulating material on the surface of the second substrate.

35. A method according to claim 12 further comprising smoothing the profiled surface of the substrate or substrates following the said single anisotropic etch.

36. A method according to claim 1 wherein the first and second connector elements are slideable relative to one another.

37. An electrical connector element in the manufacture of which the method of claim 1 is performed.

38. An electrical micro-connector comprising first and second electrical connector elements as provided by the method steps of claim 1, the electrical connector elements being mounted to one another in a sliding motion of the second connector element relative to the first connector element.

39. (canceled)

40. (canceled)
